(19) United States
(12) Patent Application Publication
(10) Pub. No.: US 2023/0251574 A1
(43) Pub. Date: Aug. 10, 2023

(54) METHOD TO ENHANCE LITHOGRAPHY PATTERN CREATION USING SEMICONDUCTOR STRESS FILM TUNING

(71) Applicant: Tokyo Electron Limited, Tokyo (JP)

(72) Inventors: Anthony R. SCHEPIS, Averill Park, NY (US); Daniel J. FULFORD, Ballston Lake, NY (US); Mark I. GARDNER, Cedar Creek, TX (US); H. Jim FULFORD, Marianna, FL (US); Anton J. DEVILLIERS, Clifton Park, NY (US)

(73) Assignee: Tokyo Electron Limited, Tokyo (JP)

(21) Appl. No.: 17/890,766

(22) Filed: Aug. 18, 2022

Related U.S. Application Data
(60) Provisional application No. 63/306,585, filed on Feb. 4, 2022.

(51) Int. Cl. G03F 7/11; G01B 11/16; G03F 7/20

(52) U.S. Cl. CPC G03F 7/11; G01B 11/16; G03F 7/70783; G03F 7/70483

(57) ABSTRACT

Aspects of the present disclosure provide a method for optimizing wafer shape. For example, the method can include receiving a wafer having a working surface for one or more devices to be fabricated thereon and a backside surface opposite to the working surface, measuring the wafer to identify bow measurement of the wafer, and forming a first stress-modification film on the backside surface. The first stress-modification film can be reactive to a first wavelength of light in that exposure to the first wavelength of light modifies an internal stress of the first stress-modification film. The method can further include exposing the first stress-modification film to a pattern of the first wavelength of light to modify the internal stress of the first stress-modification film. The pattern of the first wavelength of light corresponds to the bow measurement.

### INCORPORATION BY REFERENCE

This present disclosure claims the benefit of U.S. Provisional Application No. 63/306,585, “METHOD TO ENHANCE LITHOGRAPHY PATTERN CREATION USING SEMICONDUCTOR STRESS FILM TUNING” filed on Feb. 4, 2022, which is incorporated herein by reference in its entirety.

### FIELD OF THE INVENTION

The present disclosure relates to semiconductor fabrication, and more particularly, to wafer curvature, bow and overall wafer shape.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves multiple varied steps and processes. One typical fabrication process is known as photolithography (also called microlithography). Photolithography uses radiation, such as ultraviolet or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

Exposure systems (also called tools) are used to implement photolithographic techniques. An exposure system typically includes an illumination system, a reticle (also called a photomask) or spatial light modulator (SLM) for creating a circuit pattern, a projection system, and a wafer alignment stage for aligning a photosensitive resist-covered semiconductor wafer. The illumination system illuminates a region of the reticle or SLM with a (preferably) rectangular slot illumination field. The projection system projects an image of the illuminated region of the reticle pattern onto the wafer. For accurate projection, it is important to expose a pattern of light on a wafer that is relatively flat or planar, preferably having less than 10 microns of height deviation.

### SUMMARY

Aspects of the present disclosure provide a method to achieve optimum wafer shape. For example, the method can include receiving a wafer having a working surface for one or more devices to be fabricated thereon and a backside surface opposite to the working surface, measuring the wafer to identify bow measurement of the wafer, and forming a first stress-modification film on the backside surface. The first stress-modification film can be reactive to a first wavelength of light in that exposure to the first wavelength of light modifies an internal stress of the first stress-modification film. The method can further include exposing the first stress-modification film to a pattern of the first wavelength of light to modify the internal stress of the first stress-modification film, the pattern of the first wavelength of light corresponding to the bow measurement. In an embodiment, the first stress-modification film can be formed while the wafer is held at a periphery.

In an embodiment, measuring the wafer to identify bow measurement of the wafer can be performed prior to forming a first stress-modification film. In another embodiment, measuring the wafer to identify bow measurement of the wafer can be performed subsequent to forming a first stress-modification film.

In an embodiment, the working surface of the wafer can be with one or more devices fabricated thereon, and the method can further include forming a protection layer on the working surface of the wafer to protect the devices. For example, measuring the wafer to identify bow measurement of the wafer can be performed subsequent to forming a protection layer. As another example, measuring the wafer to identify bow measurement of the wafer can be performed prior to forming a protection layer. In another embodiment, the wafer is flipped so that the protection layer can be in contact with a wafer chuck when the first stress-modification film is formed.

In an embodiment, the method can further include executing one or more lithographic patterning processes on the working surface of the wafer. In another embodiment, the method can further include removing the first stress-modification film after the lithographic patterning processes are executed.

In an embodiment, the method can further include forming a second stress-modification film on the first stress-modification film. The second stress-modification film can be reactive to a second wavelength of light in that exposure to the second wavelength of light modifies an internal stress of the second stress-modification film. The method can further include exposing the second stress-modification film to a pattern of the second wavelength of light to modify the internal stress of the second stress-modification film, the pattern of the second wavelength of light corresponding to the bow measurement. For example, measuring the wafer to identify bow measurement of the wafer can be performed subsequent to forming a second stress-modification film.

In an embodiment, the method can further include forming a stress film on the backside surface of the wafer, and forming a first stress-modification film on the backside surface can include forming a first stress-modification film on the stress film. In another embodiment, the method can further include removing a portion of the stress film, and replacing the removed portion with a stress layer. In some embodiments, the stress layer can have a different stress type form the stress film.

Aspects of the present disclosure also provide a system to achieve optimum wafer shape. For example, the system can include a bow measurement device, a stress-modification film formation device, a light generator, and a controller coupled to the bow measurement device, the stress-modification film formation device and the light generator. The bow measurement device can be configured to measure a wafer to identify bow measurement of the wafer. The wafer can have a working surface for one or more devices to be fabricated thereon, and a backside surface opposite to the working surface. The stress-modification film formation device configured to form first and second stress-modification films. The first and second stress-modification films can be reactive to first and second wavelengths of light, respectively, such that exposure to the first and second wavelengths of light modifies internal stresses of the first and second stress-modification films, respectively. The light generator can be configured to generate patterns of first and second wavelengths of light. The controller can be configured to control the bow measurement device to measure the wafer to identify the bow measurement of the wafer, control the stress-modification film formation device to form the first and second stress-modification films on the backside surface of the wafer sequentially, and control the light generator to generate and apply the pattern of first wavelength of light onto the first stress-modification film and/or the pattern of second wavelength of light onto the second stress-modification film, the pattern of first wavelength of light and the pattern of second wavelength of light corresponding to the bow measurement.

In an embodiment, the system can further include a lithographic module coupled to the controller. The lithographic module can be configured to be controlled by the controller to form a stress film on the backside surface of the wafer, remove a portion of the stress film, and replace the removed portion of the stress film with a stress layer. For example, the stress layer can have a different stress type from the stress film.

In an embodiment, the controller can be configured to control the stress-modification film formation device to form the first stress-modification film or the first and second stress-modification films on the stress film. In another embodiment, the controller can be configured to first control the stress-modification film formation device to form the first stress-modification film or the first and second stress-modification films on the backside surface of the wafer and then control the bow measurement device to measure the wafer to identify the bow measurement of the wafer.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A to 1C show first and second order bowing of a wafer.

FIG. 2 is a functional block diagram of an exemplary system for achieving an optimum wafer shape, in accordance to some embodiments of the present disclosure;

FIGS. 3 to 9 show an exemplary method used to optimize wafer shape of a semiconductor structure, in accordance with a first embodiment of the present disclosure;

FIGS. 10 to 13 show an exemplary method used to optimize wafer shape of a semiconductor structure, in accordance with a second embodiment of the present disclosure;

FIGS. 14 to 19 show an exemplary method used to optimize wafer shape of a semiconductor structure, in accordance with a third embodiment of the present disclosure;

FIGS. 20 and 21 show an exemplary method used to optimize wafer shape of a semiconductor structure, in accordance with a fourth embodiment of the present disclosure;

FIGS. 22 to 25 show an exemplary method used to optimize wafer shape of a semiconductor structure, in accordance with a fifth embodiment of the present disclosure;

FIGS. 26 to 30 show an exemplary method used to optimize wafer shape of a semiconductor structure, in accordance with a sixth embodiment of the present disclosure; and

FIGS. 31 to 33 show an exemplary method used to optimize wafer shape of a semiconductor structure, in accordance with a seventh embodiment of the present disclosure.

### DETAILED DESCRIPTION

To achieve the best resolution using a mask with a laser or EMS λ (electromagnetic spectrum wavelength) sensitive lithographic emulsion to define areas that are either blocked or opened for a subsequent pattern transfer or implant requires the wafer surface to be of optimum shape prior to the photo/lithographic process. Techniques disclosed herein include stress modulation of films on a wafer to achieve a target curvature or correction. Techniques herein can use all types of light sensitive wavelengths/lithography types in the electromagnetic spectrum (some examples are photo lithography, e-beam lithography, direct laser write, and x-ray lithography).

Techniques disclosed herein define several process flows to achieve the optimum starting wafer shape (using semiconductor stress film tuning, or tuning the lattice thereof) prior to the photo process that is used on the working surface of the wafer. Process flows herein include a disposable stress tuning film on the backside surface of a wafer as one option. Another option is to leave the stress tuning film in place for subsequent processing to be used in some cases where low temp processing is possible for several steps.

By using a lithographic film that may be patterned either with a mask or direct write with lithographic stress film feature. One unique aspect herein is the deposited lithographic film can be either compressive, tensile, or neutral stress in the deposited condition as a lithographic emulsion sensitive to a certain laser or EM wavelength. Thus the micro stress regions may be defined by either mask and etch of the deposited film, or direct write regions where selective compressive/neutral/tensile regions are desired (or direct write options). The process may be also be replicated with two different depositions (i.e., one sensitive to a first laser wavelength, the other sensitive to a second laser wavelength) to eliminate wafer bow post laser treatment.

Techniques herein include wafer stress modification techniques to modify wafer bowing and curvature to improve wafer overlay. Stress film deposition can be executed with wafer surface up or down as options for all process flows for all flows with clamped wafer option.

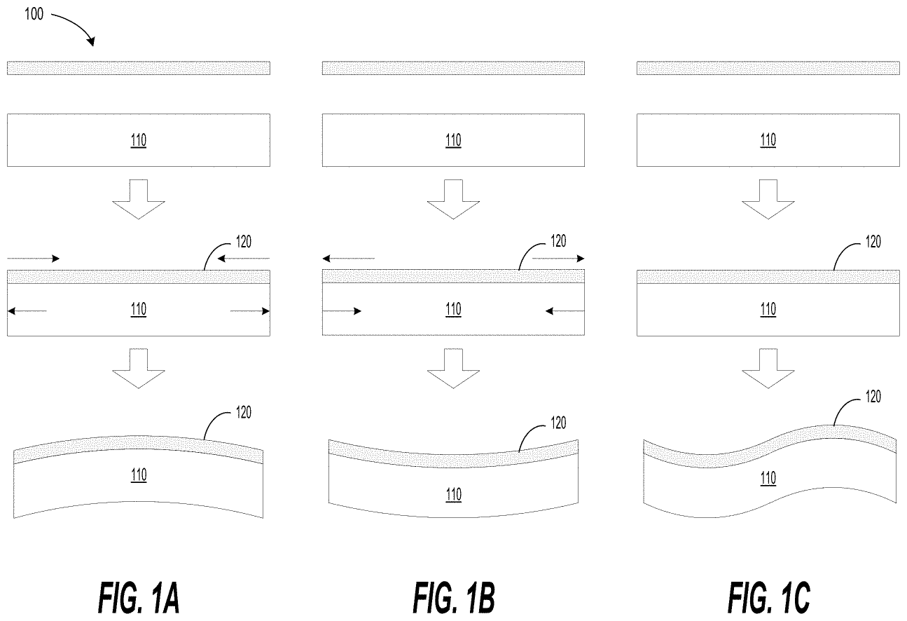

Microfabrication of a semiconductor structure 100 begins with a flat substrate or wafer 110, as those illustrated in FIGS. 1A to 1C. During microfabrication of the semiconductor structure 100, multiple processing steps are executed that can include depositing material on the substrate 110, removing material, implanting dopants, annealing, baking, and so forth. Different materials and structural formations 120 thus formed can cause internal stresses in the substrate 110 which result in bowing of the semiconductor structure 100, which in turn affects overlay and typically results in overlay errors of various magnitudes. For example, FIGS. 1A and 1B show how the different materials and structural formations 120 can either induce a compressive or tensile stress in the substrate 110, respectively, resulting in first order bowing with bow measurements illustrating z-direction height deviations from a reference plane (not shown). As another example, FIG. 1C shows second order bowing of the substrate 110 with two bow measurements identifying positive and negative z-direction height deviations, respectively.

If a region of the substrate 110 initially contains compressive stress or tensile stress, the opposite type of stress may be applied in a localized nano stress region. Techniques herein may use laser-sensitive lithographic films to produce stress. Particular films can react to actinic radiation and change their stress type and magnitude. Other films can be patterned with an etch mask. For example, a stress-modification film is deposited, and then a layer of photoresist is deposited on the stress-modification film. The layer of photoresist is patterned and developed, to result in a relief pattern or etch mask. This etch mask is used to etch the underlying stress-modification film to release or induce stresses according to the etch mask.

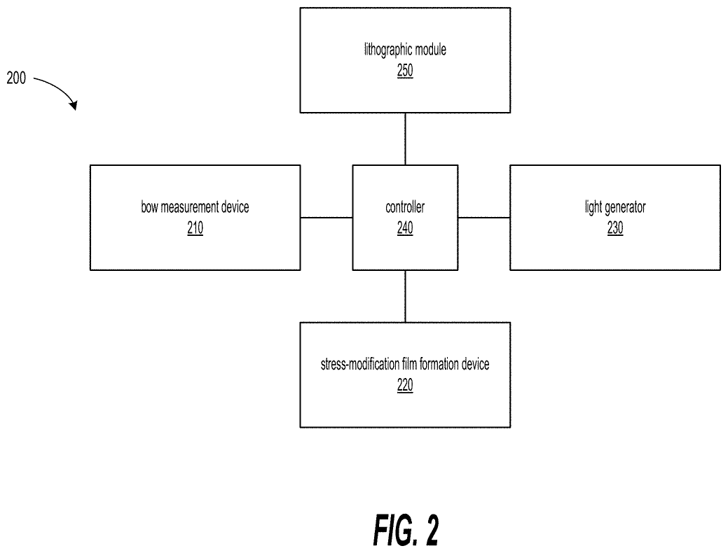

FIG. 2 is a functional block diagram of an exemplary semiconductor processing system 200 for achieving an optimum wafer shape, in accordance to some embodiments of the present disclosure. For example, the system 200 can include metrology equipment, e.g., a bow measurement device 210, which is configured to measure a substrate or a wafer (e.g., the substrate 110 shown in FIG. 1) to identify bow measurement of the wafer. In an embodiment, the bow measurement device 210 can use optical (e.g., using a scanning laser technique), acoustic and other mechanisms to measure the z-direction height deviations across a surface of the wafer and store the height deviations by (x, y) coordinates in order to identify a plurality of sub-bow measurements (x, y) of the bow measurement. The z-direction height deviations can be mapped at various resolutions depending on type of metrology equipment used and/or a resolution desired. The bow measurement (and the sub-bow measurements as well) can include raw bow data, or be represented as a bow signature with relative values. In an embodiment, the wafer has a working surface and a backside surface opposite to the working surface. The wafer may have an amount of wafer bow as a result from one or more micro fabrication processing steps that have been executed to create at least part of a semiconductor structure on the working surface of the wafer. For example, transistor gates may be completed or only partially completed.

The system 200 further includes a deposition module or a spin-coating module, e.g., a stress-modification film formation device 220, which is configured to deposit and form a stress-modification film on the backside surface and/or the working surface of the wafer. The stress-modification film, when exposed and reactive to light, may have its internal stress modified by the exposure to the light. The stress-modification film formation device 220 can be configured to form two or more stress-modification films of different, e.g., opposing, stresses.

The system 200 further includes a light generator 230, which is configured to generate a pattern of light. In an embodiment, the bow measurement device 210 can measure a wafer to identify bow measurement of the wafer, which includes a plurality of sub-bow measurements that correspond to the pattern of light. The light generator 230 can generate a plurality of wavelengths of light.

The system 200 further includes a lithographic module 250, which may include a plurality of components, such as a wafer chuck for a wafer to be placed thereon, a robot handler configured to flip the wafer, a wafer damper configured to clamp a wafer, a bake device configured to bake the photoresist, an imaging device configured to expose the photoresist to an actinic radiation patter, a development device configured to develop a latent image in the photoresist, and an etching device configured to use plasma or vapor-phase etching or wet etching.

The system 200 further includes a controller 240, which is coupled to the bow measurement device 210, the stress-modification film formation device 220, the light generator 230 and the lithographic module 250. The controller 240 is configured to control the bow measurement device 210 to measure the wafer to identify the bow measurement (and the sub-bow measurements) of the wafer, control the stress-modification film formation device 220 to form the stress-modification film(s) on the backside surface and/or the working surface of the wafer, control the light generator 230 to generate and apply patterns of different wavelengths of light onto the stress-modification film(s), the patterns of different wavelengths of light corresponding to the bow measurement (and the sub-bow measurements), and control the lithographic module 250 to form a stress film, etch and remove a portion of the stress film and replace the removed portion of the stress film with neutral stress, tensile stress, or compressive stress materials.

Alternatively, or in addition, the controller 240 can be coupled to one or more additional controllers/computers (not shown), and the controller 240 can obtain setup and/or configuration information from an additional controller/computer. The controller 240 can be used to configure any or all of the elements of the system 200, and the controller 240 can collect, provide, process, store, and display data from any or all of the tool components. The controller 240 can comprise a number of applications for controlling any or all of the tool components. For example, the controller 240 can include a graphic user interface (GUI) component that can provide easy to use interfaces that enable a user to monitor and/or control one or more tool components.

The controller 240 can include a microprocessor, memory, and a digital I/O port capable of generating control voltages sufficient to communicate, activate inputs, and exchange information with the semiconductor processing system 200 as well as monitor outputs from the semiconductor processing system 200. For example, a program stored in the memory may be utilized to activate the inputs of the lithographic module 250 and/or stress-modification film formation device 220 according to a process recipe in order to perform integrated substrate processing. The controller 2400 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 240 may be locally located relative to the system 200, or it may be remotely located relative to the system 200. For example, the controller 240 may exchange data with the system 200 using at least one of a direct connection, an intranet, the Internet and a wireless connection. The controller 240 may be coupled to an intranet at, for example, a customer site (i.e., a device maker, etc.), or it may be coupled to an intranet at, for example, a vendor site (i.e., an equipment manufacturer). Additionally, for example, the controller 240 may be coupled to the Internet. Furthermore, another computer (i.e., controller, server, etc.) may access, for example, the controller 240 to exchange data via at least one of a direct connection, an intranet, and the Internet. As also would be appreciated by those skilled in the art, the controller 240 may exchange data with the system 200 via a wireless connection.

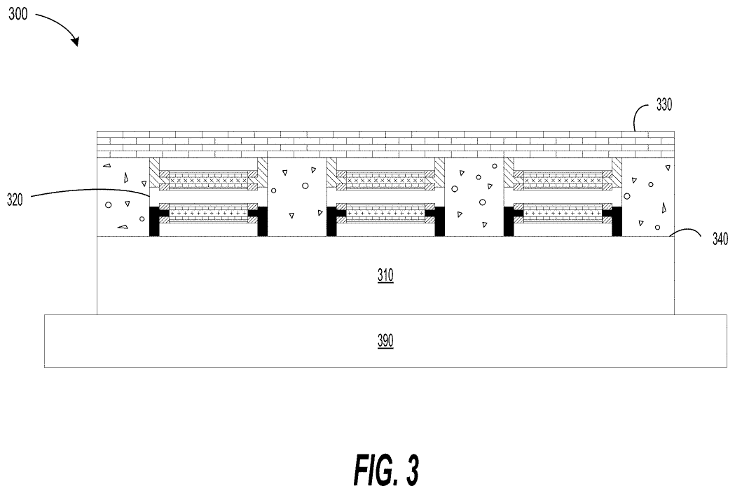

FIGS. 3 to 9 show an exemplary method, which is used to optimize wafer shape of a semiconductor structure 300, in accordance with a first embodiment of the present disclosure. In the exemplary method of the first embodiment, a stress-modification film that is reactive to light is deposited and formed on a backside surface of a wafer, and is exposed to the light such that an internal stress of the stress-modification film is modified based on bow measurement of the wafer. As shown in FIG. 3, the semiconductor structure 300 is placed on a wafer chuck 390. The semiconductor structure 300 may include a substrate 310 and one or more semiconductor devices 320 fabricated on a working surface 340 of the substrate 310 through stack of 3D gate-all-around (GAA) nano sheets. The semiconductor devices 320 can include logic gates, memories and/or other components. For example, the semiconductor devices 320 can include complementary field-effect transistors (CFETs). A protection layer 330 can be formed on the working surface 340 of a wafer (including the substrate 310 and the semiconductor devices 320) to protect the semiconductor devices 320.

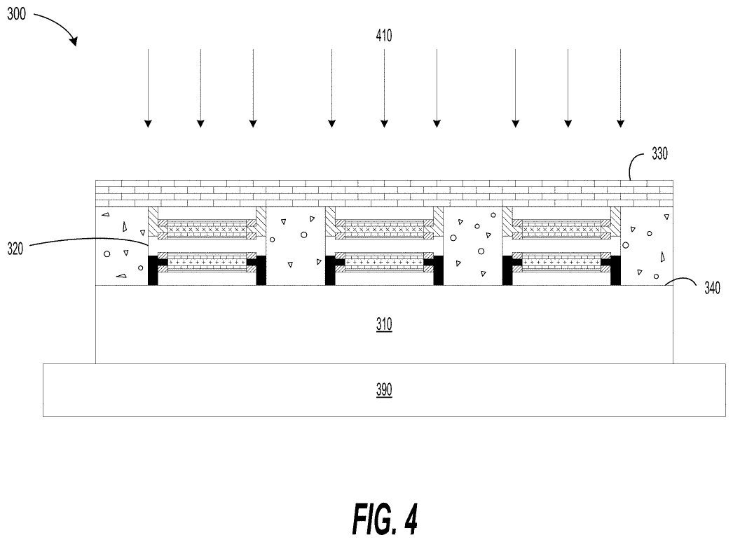

As shown in FIG. 4, a scanning laser technique 410 can be used, e.g., by the bow measurement device 210, to measure the z-direction height deviations across the surface of the wafer and store the height deviations by (x, y) coordinates in order to identify the sub-bow measurements of the bow measurement of the wafer. Each wafer has unique stress/bow measurement, and thus each wafer requires stress measurement. Conventional and emerging metrology tools can be used to measure or scan the surface of the wafer. Thus, bow measurement of a wafer herein is a map of coordinate locations of z-direction height values or wafer curvature.

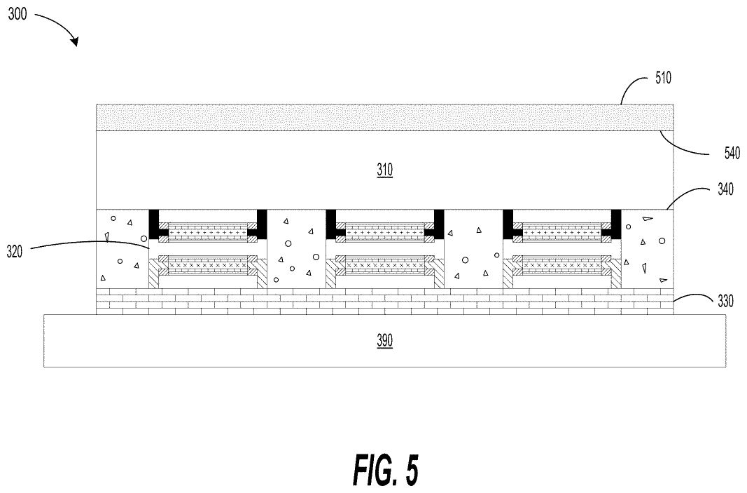

As shown in FIG. 5, the wafer is flipped upside down, and then a stress-modification film 510 can be formed, e.g., by the stress-modification film formation device 220, and applied onto a backside surface 540 of the wafer. The stress-modification film 510, e.g., an epoxy film, can be reactive to light in that exposure the stress-modification film 510 to the light modifies an internal stress of the stress-modification film 510. For example, the stress-modification film 510 can have a neutral internal stress, and be exposed and reactive to a pattern of light generated by the light generator 230 and modified to become compressive or tensile at various locations corresponding to the pattern of light. In some embodiments, the stress-modification film 510 may be initially compressive or tensile, and the scanning laser technique 410 is used, after the stress-modification film 510 is formed, to measure the z-direction height deviations across the surface of the wafer (including the stress-modification film 510) and store the height deviations by (x, y) coordinates in order to identify the sub-bow measurements of the bow measurement of the wafer (including the stress-modification film 510).

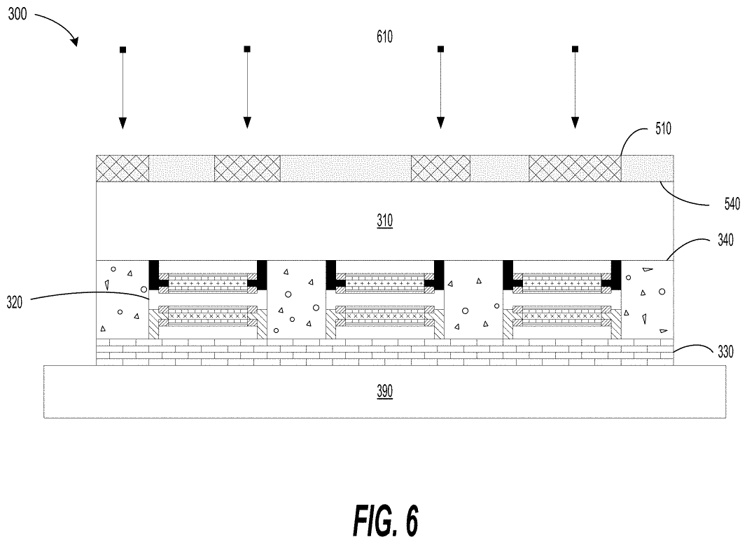

As shown in FIG. 6, a pattern of light 610 is then generated, e.g., by the light generator 230, based on the sub-bow measurements of the bow measurement of the wafer, and the stress-modification film 510 is exposed to the pattern of light 610 such that the pattern of light 610 modifies the internal stress of the stress-modification film 510, which corresponds to the sub-bow measurements. Therefore, the modified internal stress of the stress-modification film 510 corresponds to the bow measurement of the wafer, and the wafer is close to being flat or considered flat.

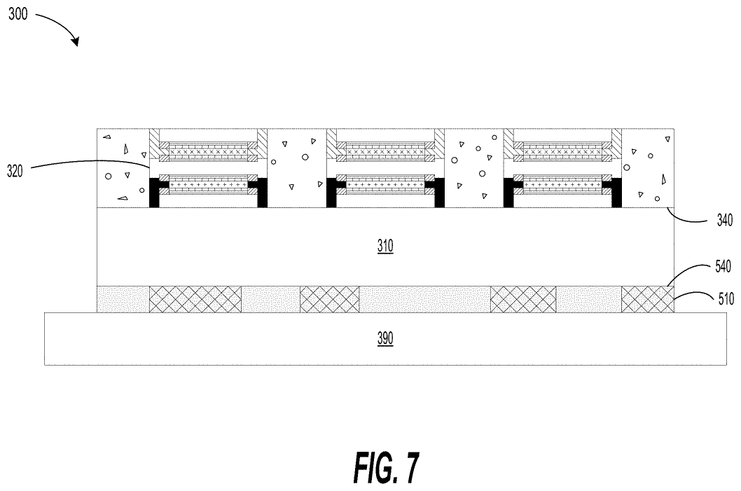

As shown in FIG. 7, the wafer is flipped again, and then the protection layer 330 (shown in FIG. 6) is removed. The semiconductor structure 300 can then be ready to be processed through masking step with the stress-modification film 510, which has its internal stress modified, to obtain a photo pattern (not shown).

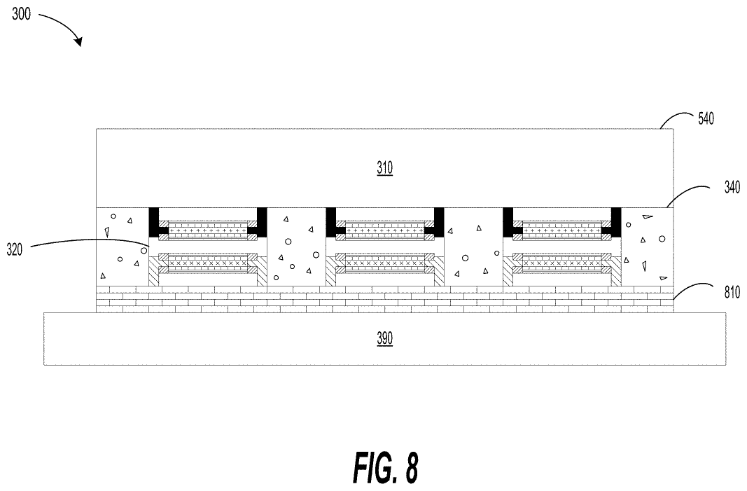

As shown in FIG. 8, a protection layer 810 is formed on the working surface 340 of the wafer to protect the devices fabricated during the masking step, the wafer is flipped again, and the stress-modification film 510 (shown in FIG. 7) is removed. Stress memorization can also be used herein. In some embodiments, even though the stress-modification film 510 is removed, the semiconductor lattice still has a memory effect because the stress of the stress-modification film 510 has been transferred to the silicon lattice.

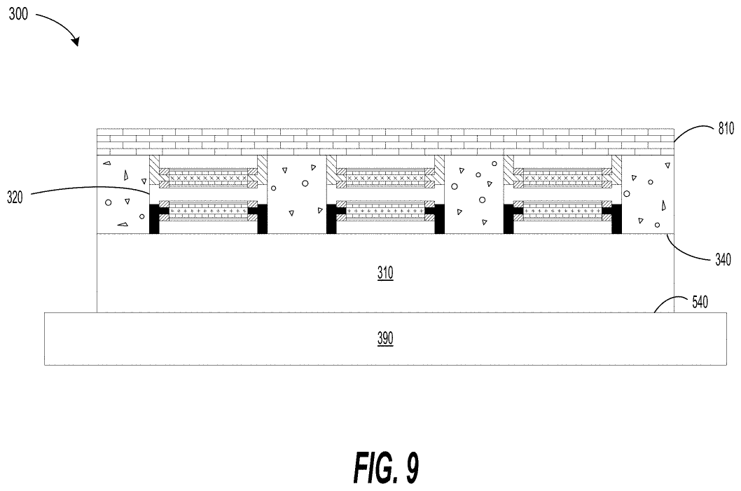

As shown in FIG. 9, the wafer is flipped, and then next backside stress photo sequences can be repeated.

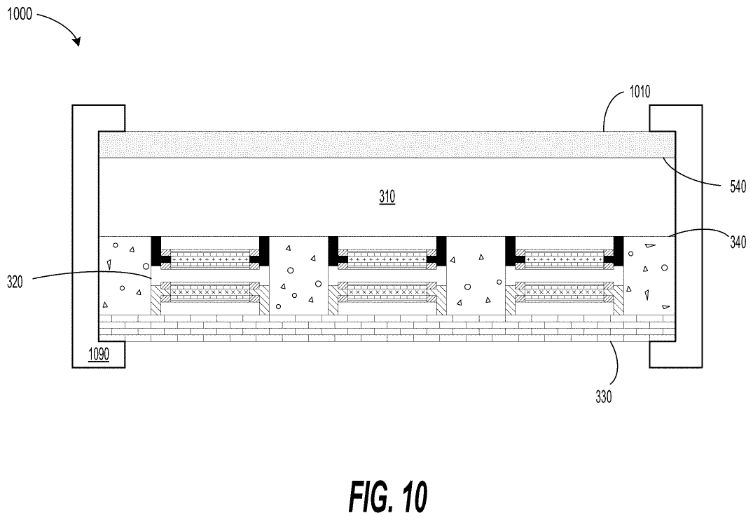

FIGS. 10 to 13 show an exemplary method, which is used to optimize wafer shape of a semiconductor structure 1000, in accordance with a second embodiment of the present disclosure. In the exemplary method of the second embodiment, the wafer is clamped by a wafer damper when a stress-modification film is formed. As shown in FIG. 10, which follows FIGS. 3 and 4, the wafer is flipped upside down and clamped by a wafer clamper 1090, with the backside surface 540 and the protection layer 330 exposed, and a stress-modification film 1010 is deposited and formed onto the backside surface 540 of the wafer. The stress-modification film 1010 can initially be compressive, stress, neutral stress or tensile stress.

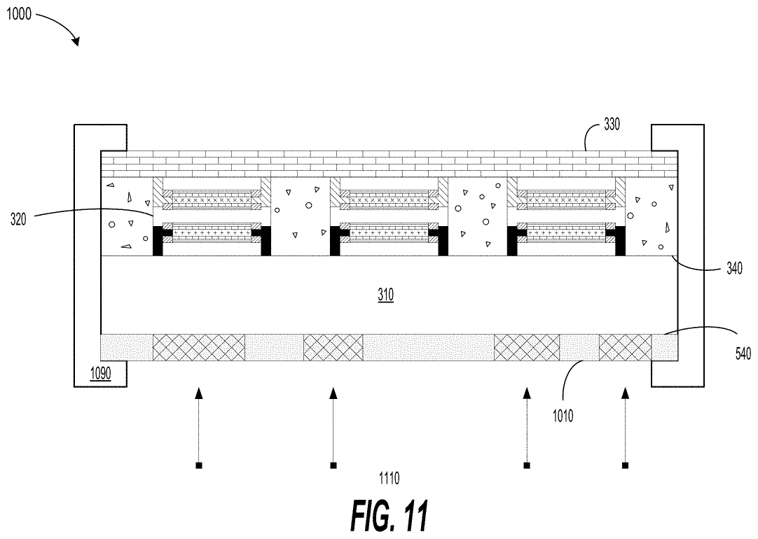

As shown in FIG. 11, the stress-modification film 1010 is exposed to a pattern of light 1110, which corresponds to (the sub-bow measurements of) the bow measurement of the wafer, and has its internal stress modified accordingly. In the example embodiment, the pattern of light (and the light generator 230) is located underneath the wafer since the wafer is clamped by the wafer damper 1090 such that the backside surface 540 of the wafer is open to light (e.g., laser) treatment.

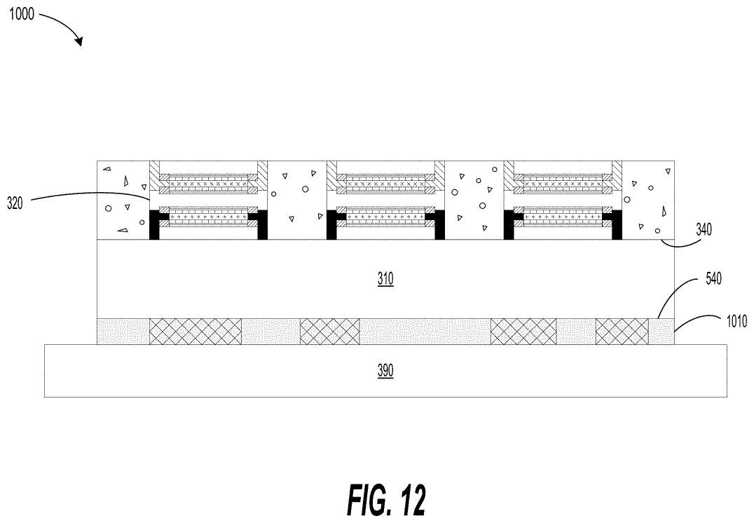

As shown in FIG. 12, the protection layer (shown in FIG. 11) is removed, and the wafer is placed back on the wafer chuck 390. The semiconductor structure 1000 can then be ready to be processed through masking step with the stress-modification film 1010, which has its internal stress modified, to obtain a photo pattern (not shown).

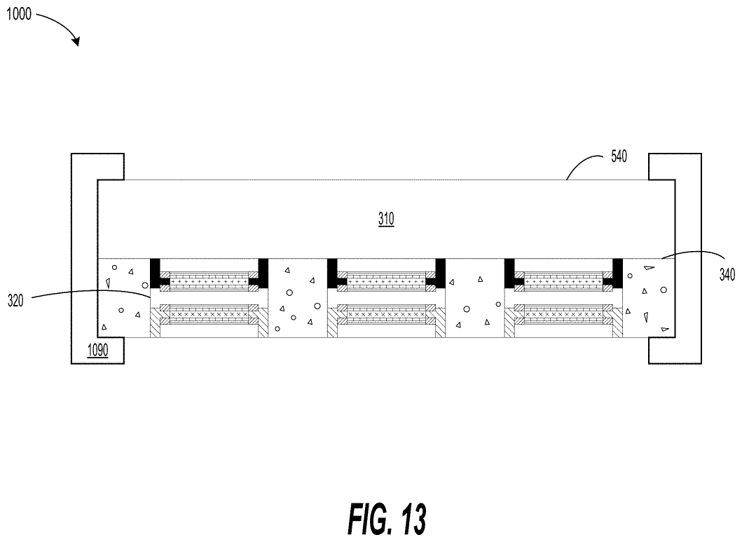

As shown in FIG. 13, the wafer is clamped by the wafer damper 1090 and flipped upside down again, and the stress-modification film 1010 (shown in FIG. 12) is removed. The wafer can be flipped over again, and then next backside stress photo sequences can be repeated.

In the exemplary method of the first embodiment shown in FIGS. 10 to 13, the stress-modification film 1010 can be replaced by another stress-modification film, which can be patterned and etched based on the bow measurement of the wafer, using direct write (or mask/etch) with a laser wavelength different from that used in the pattern of light 1110.

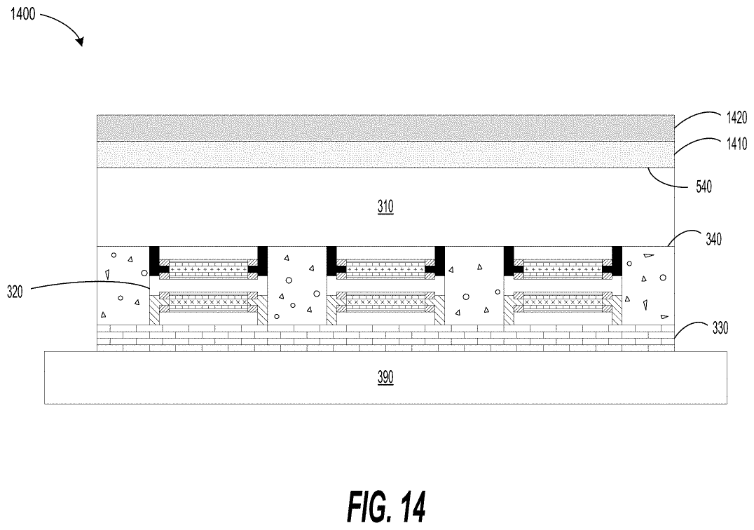

FIGS. 14 to 19 show an exemplary method, which is used to optimize wafer shape of a semiconductor structure 1400, in accordance with a third embodiment of the present disclosure. In the exemplary method of the third embodiment, two stress-modification films are formed on a backside surface of a wafer and exposed to two patterns of light that have different wavelengths. As shown in FIG. 14, which follows FIGS. 3 and 4, the wafer is flipped upside down and placed on the wafer chuck 390, and a first stress-modification film 1410 and a second stress-modification film 1420 are deposited and formed onto the backside surface 540 of the wafer sequentially. The first and second stress-modification films 1410 and 1420 can initially be compressive, stress, neutral stress or tensile stress. The first stress-modification film 1410 is sensitive to laser with a first wavelength, and the second stress-modification film 1420 is sensitive to laser with a second wavelength. Exposure the first and second stress-modification films 1410 and 1420 to the laser with the first and second wavelengths, respectively, will modify their internal stresses, which can be neutral, compressive or tensile stresses.

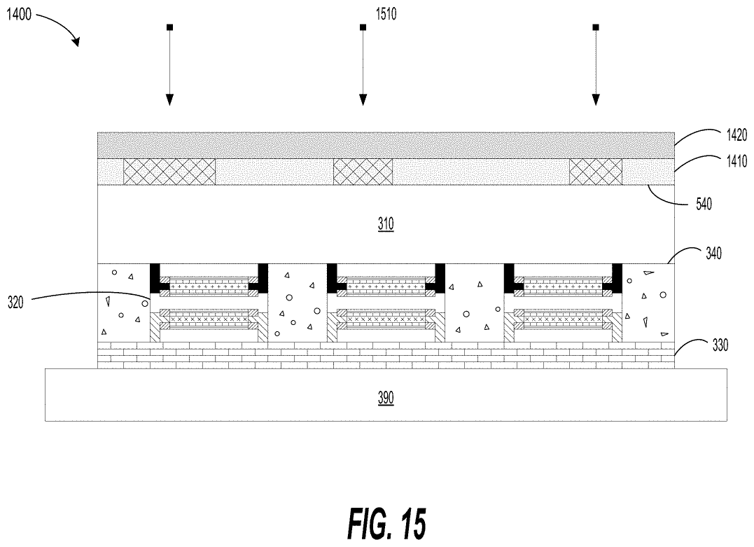

As shown in FIG. 15, a pattern of light (or laser) 1510 (e.g., using direct write) with the first wavelength is generated based on (the sub-bow measurements of) the bow measurement of the wafer, and the first stress-modification film 1410 is exposed to the pattern of light 1510 such that the pattern of light 1510 modifies the internal stress of the first stress-modification film 1410. Then, the semiconductor structure 1400 can be rinsed in lithographic chemicals to remove the first film-modification film 1410 in un-desired regions.

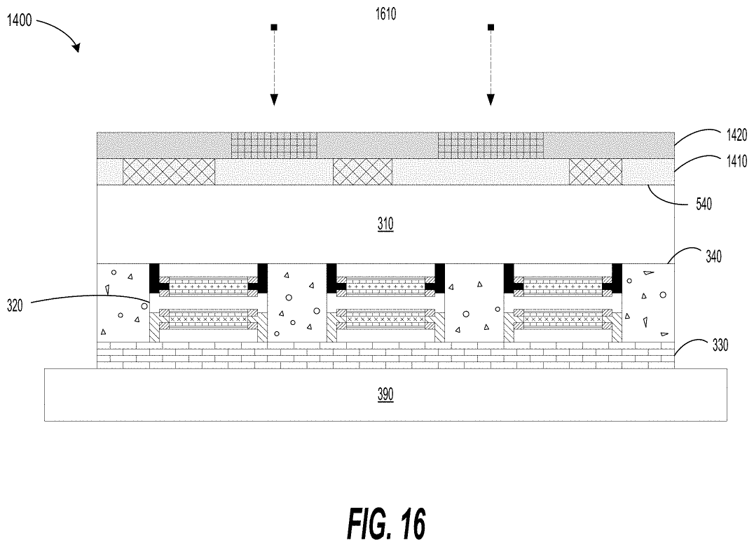

As shown in FIG. 16, another pattern of light (or laser) 1610 (e.g., using direct write) with the second wavelength is generated based on (the sub-bow measurements of) the bow measurement of the wafer, and the second stress-modification film 1420 is exposed to the pattern of light 1610 such that the pattern of light 1610 modifies the internal stress of the second stress-modification film 1420. Then, the semiconductor structure 1400 is rinsed in lithographic chemicals to remove the second film-modification film 1420 in un-desired regions. Therefore, the modified internal stresses of the first and second stress-modification films 1410 and 1420 correspond to the bow measurement of the wafer, and the wafer is close to being flat or considered flat.

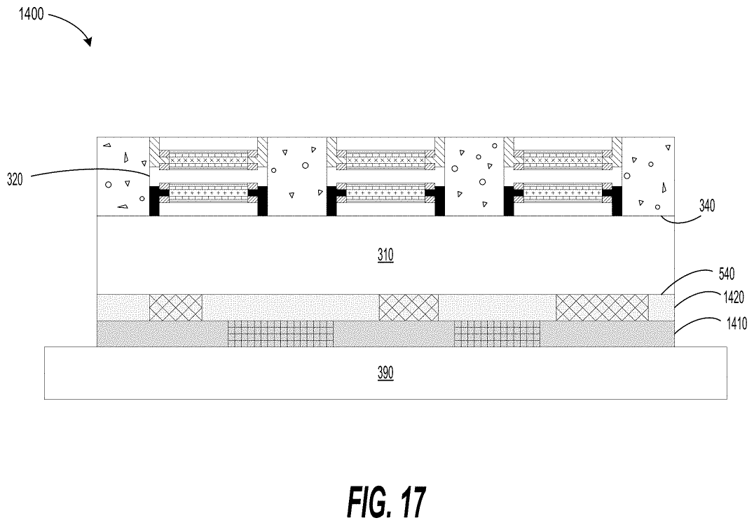

As shown in FIG. 17, the wafer is flipped, and the protection layer 330 (shown in FIG. 16) is removed. The semiconductor structure 1400 can then be ready to be processed through masking step with the first and second stress-modification film 1410 and 1420, which have their internal stresses modified, to obtain precision photo pattern (not shown).

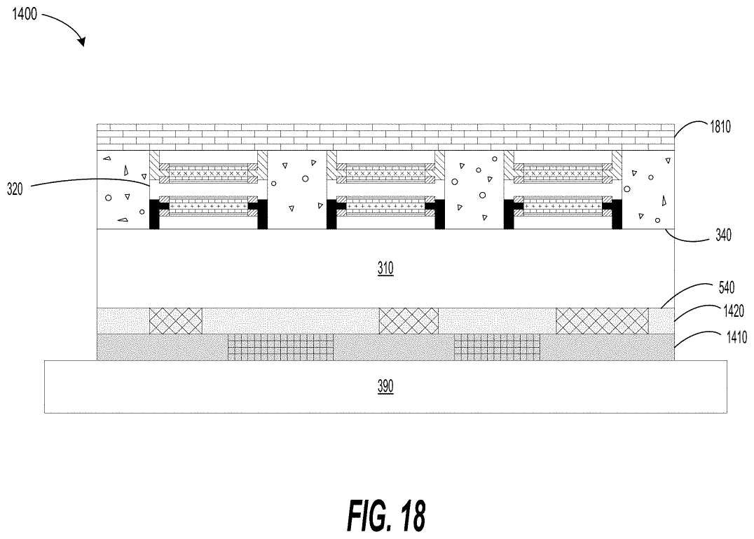

As shown in FIG. 18, a protection layer 1810 is formed on the working surface 340 of the wafer to protect the devices fabricated during the masking step.

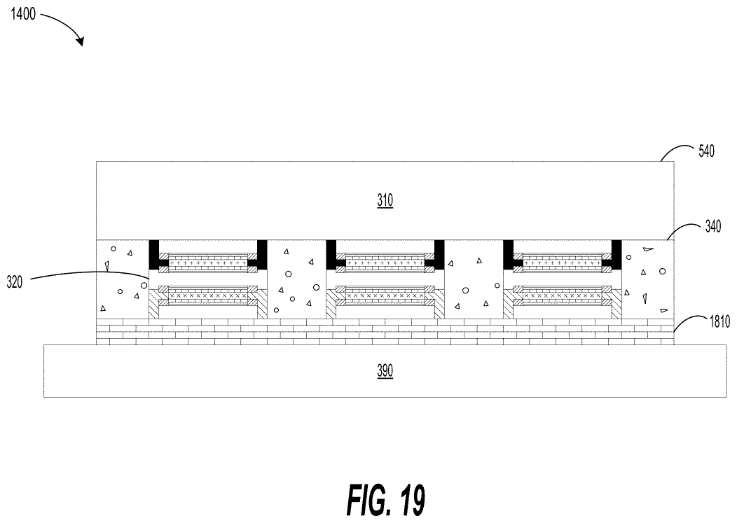

As shown in FIG. 19, the wafer is flipped again, and the first and second stress-modification films 1410 and 1420 are removed. Then next backside stress photo sequences can be repeated.

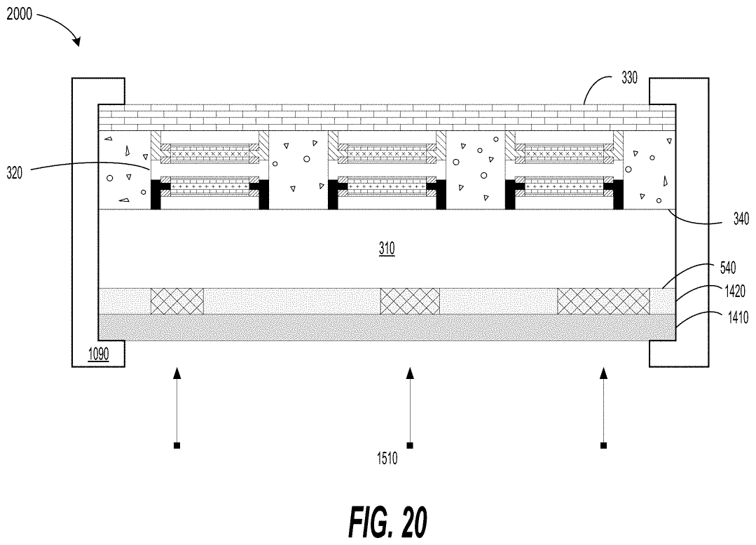

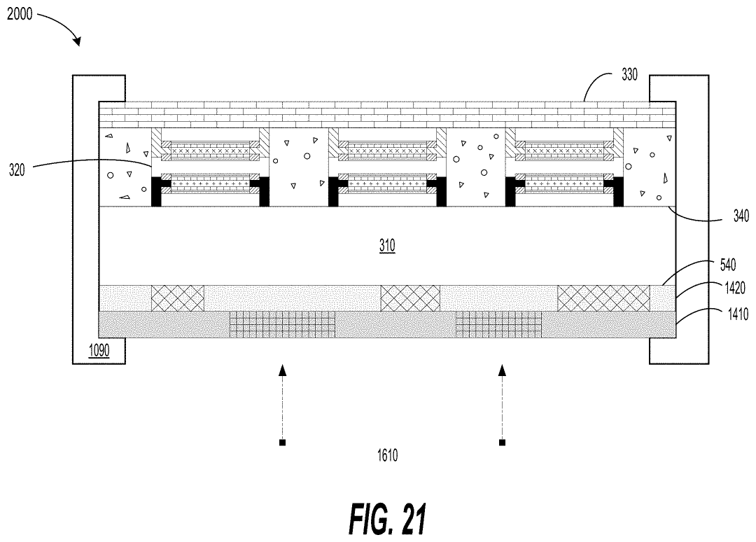

FIGS. 20 to 21 show an exemplary method, which is used to optimize wafer shape of a semiconductor structure 2000, in accordance with a fourth embodiment of the present disclosure. The fourth embodiment differs from the third embodiment in that in the fourth embodiment the wafer chuck 390 is replaced with the wafer damper 1090. As shown in FIG. 20, which follows FIG. 14, the wafer is flipped upside down and clamped by the wafer damper 1090, with the first and second stress-modification films 1410 and 1420 and the protection layer 330 exposed, and the first stress-modification film 1410 is exposed to the pattern of light 1510 such that the pattern of light 1510 modifies the internal stress of the first stress-modification film 1410.

As shown in FIG. 21, the second stress-modification film 1420 is exposed to the pattern of light 1610 such that the pattern of light 1610 modifies the internal stress of the second stress-modification film 1420.

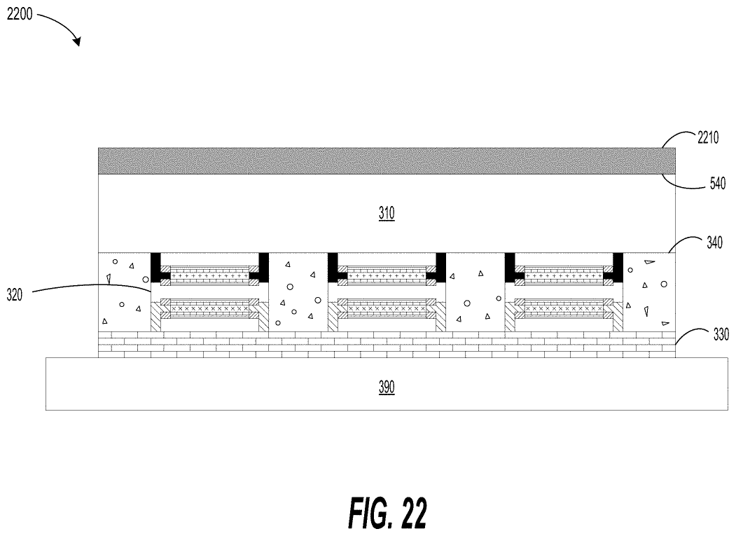

FIGS. 22 to 25 show an exemplary method, which is used to optimize wafer shape of a semiconductor structure 2200, in accordance with a fifth embodiment of the present disclosure. In the exemplary method of the fifth embodiment, single blanket nitride (first compressive or tensile film example) or single blanket oxide (first compressive or tensile film example) that handles global wafer shape correction is formed on a backside surface of a wafer, and a stress-modification film reactive to light is formed on the single blanket nitride or oxide for local wafer shape correction. As shown in FIG. 22, which follows FIG. 3, the wafer is flipped upside down, and a global stress film (compressive or tensile) 2210 is formed on the backside surface 540 of the wafer.

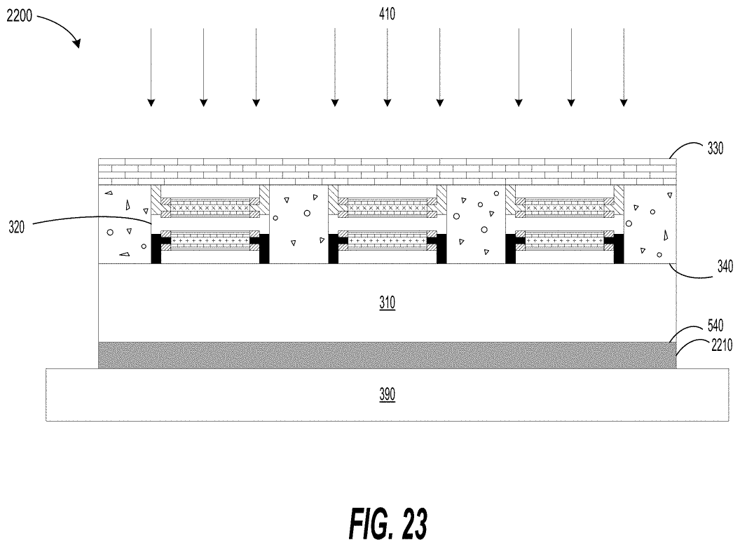

As shown in FIG. 23, the wafer is flipped, and the scanning laser technique 410 can be used to measure the z-direction height deviations across the surface of the wafer and store the height deviations by (x, y) coordinates in order to identify the sub-bow measurements of the bow measurement of the wafer.

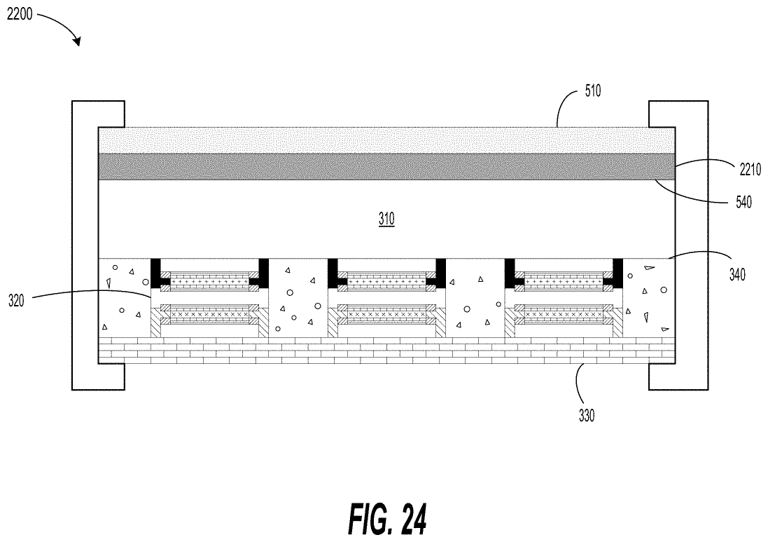

As shown in FIG. 24, the wafer is flipped upside down, and a stress-modification film, e.g., the stress-modification film 510, can be formed on the global stress film 2210.

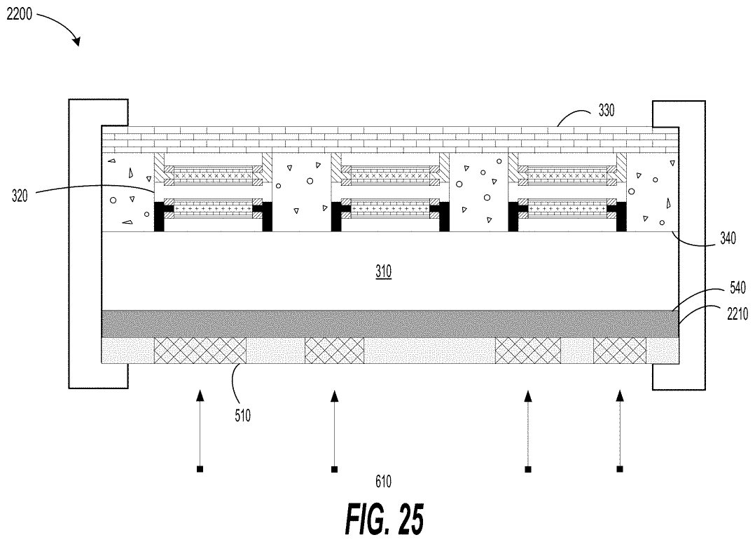

As shown in FIG. 25, a pattern of light, e.g., the pattern of light 610, is then generated based on the sub-bow measurements of the bow measurement of the wafer, and the stress-modification film 510 is exposed to the pattern of light 610 such that the pattern of light 610 modifies the internal stress of the stress-modification film 510, which corresponds to the sub-bow measurements.

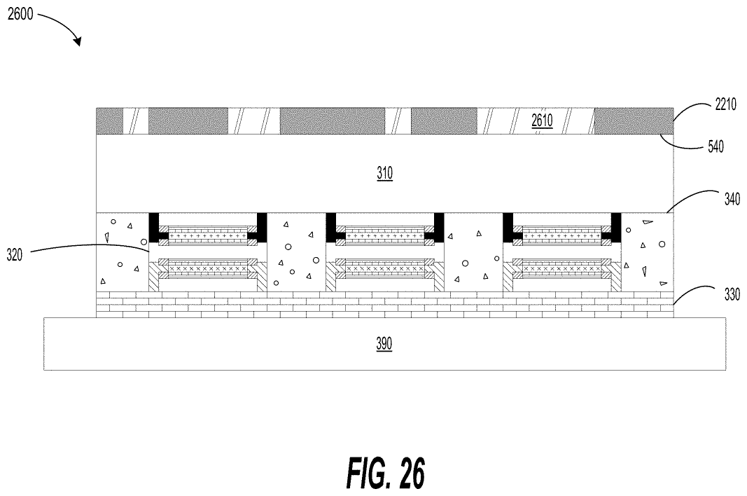

FIGS. 26 to 30 show an exemplary method, which is used to optimize wafer shape of a semiconductor structure 2600, in accordance with a sixth embodiment of the present disclosure. In the exemplary method of the sixth embodiment, single blanket nitride (first compressive or tensile film example) or single blanket oxide (first compressive or tensile film example) that handles global wafer shape and coarse local shape correction is formed on a backside surface of a wafer, and a stress-modification film reactive to light is formed on the single blanket nitride or oxide for fine local wafer shape correction. As shown in FIG. 26, which follows FIG. 22, the global stress film 2210 is patterned and etched, and then a stress layer 2610 is deposited, followed by chemical-mechanical polishing (CMP) to ensure the wafer flat. The stress layer 2610 may have a different stress type from the global stress film 2210. For example, the stress layer 2610 has a neutral stress.

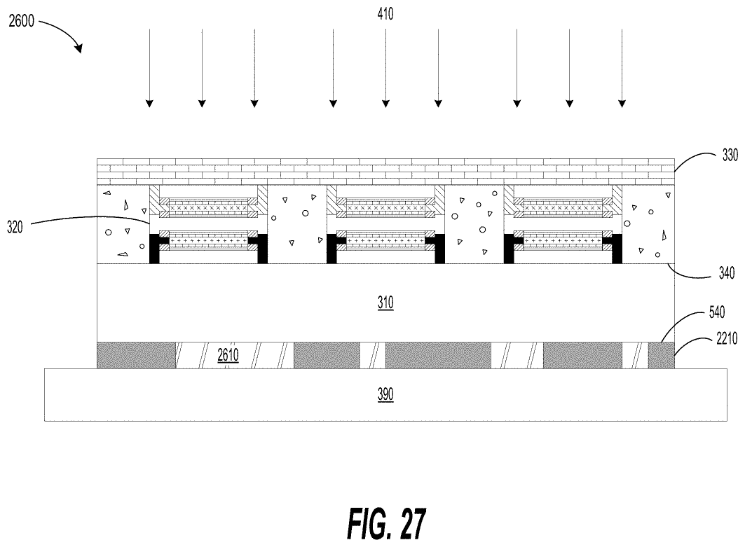

As shown in FIG. 27, the wafer is flipped upside down, and the scanning laser technique 410 can be used to measure the z-direction height deviations across the surface of the wafer and store the height deviations by (x, y) coordinates in order to identify the sub-bow measurements of the bow measurement of the wafer.

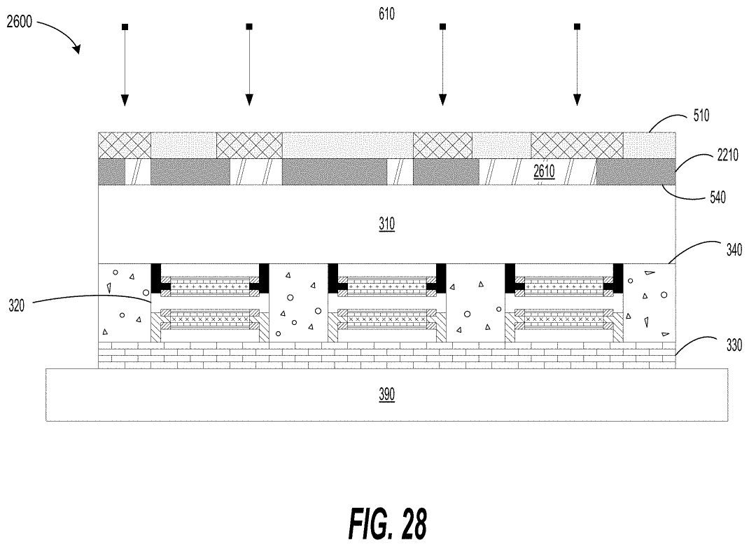

As shown in FIG. 28, the wafer is flipped, and a stress-modification film, e.g., the stress-modification film 510 is formed on the global stress film 2210. A pattern of light, e.g., the pattern of light 610, is then generated based on the sub-bow measurements of the bow measurement of the wafer, and the stress-modification film 510 is exposed to the pattern of light 610 such that the pattern of light 610 modifies the internal stress of the stress-modification film 510, which corresponds to the sub-bow measurements. Therefore, the wafer is close to being flat or considered flat.

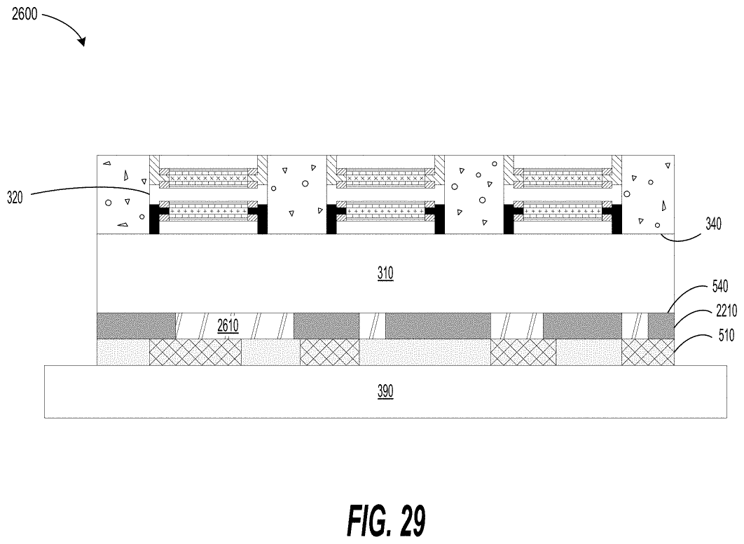

As shown in FIG. 29, the wafer is flipped, and the protection layer (shown in FIG. 28) is removed. The semiconductor structure 2600 can then be ready to be processed through masking step with the stress-modification film 510, which has its internal stress modified, to obtain a photo pattern (not shown).

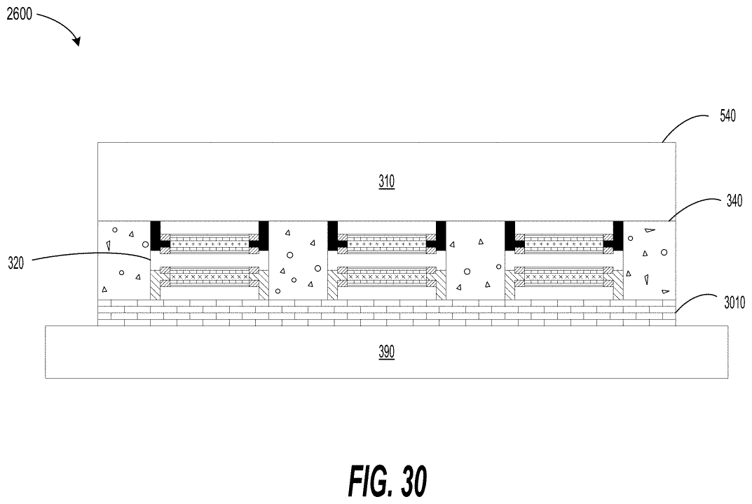

As shown in FIG. 30, a protection layer 3010 is formed on the working surface 340 of the wafer to protect the devices fabricated during the masking step, the wafer is flipped again, and the stress-modification film 510 (shown in FIG. 29) is removed.

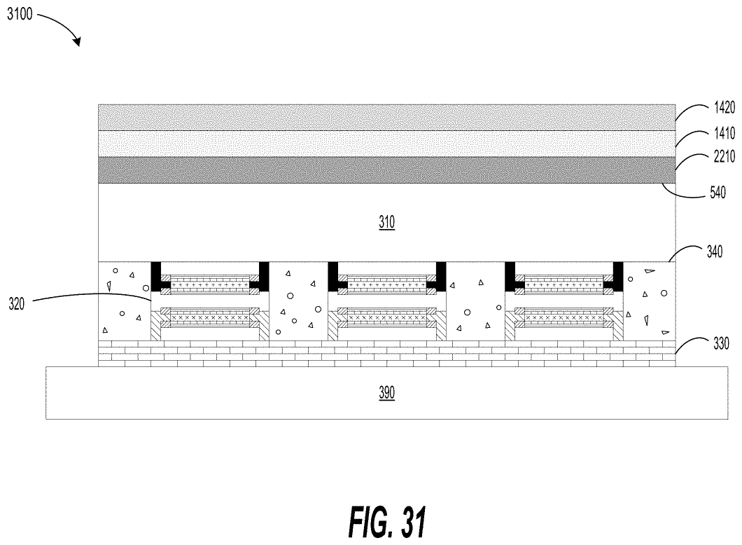

FIGS. 31 to 33 show an exemplary method, which is used to optimize wafer shape of a semiconductor structure 3100, in accordance with a seventh embodiment of the present disclosure. In the exemplary method of the seventh embodiment, single blanket nitride (first compressive or tensile film example) or single blanket oxide (first compressive or tensile film example) that handles global wafer shape is formed on a backside surface of a wafer, and two stress-modification films reactive to light of different wavelengths are formed on the single blanket nitride or oxide sequentially for fine local wafer shape correction. As shown in FIG. 31, which follows FIGS. 22 and 23, the wafer is flipped upside down, and two stress-modification films, e.g., the first and second stress-modification films 1410 and 1420, are formed on the global stress film 2210 sequentially.

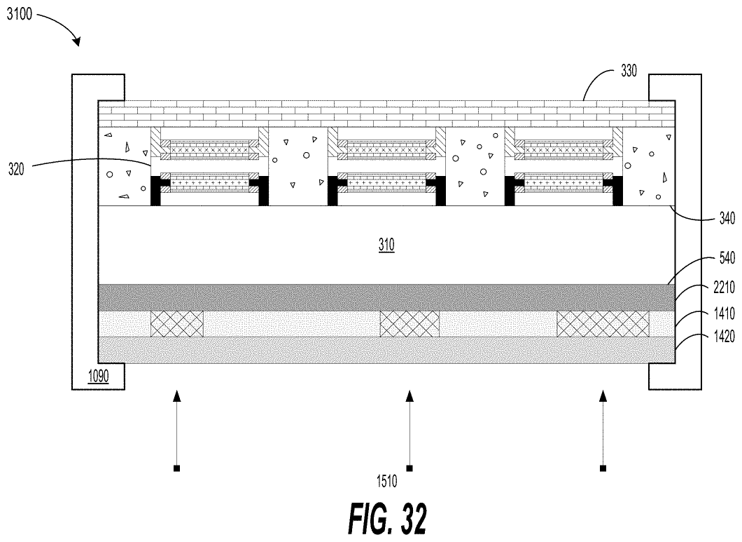

As shown in FIG. 32, the wafer is flipped and clamped by the wafer clamper 1090, a pattern of light, e.g., the pattern of light 1510, is generated, and the first stress-modification film 1410 is exposed to the pattern of light 1510 such that the pattern of light 1510 modifies the internal stress of the first stress-modification film 1410.

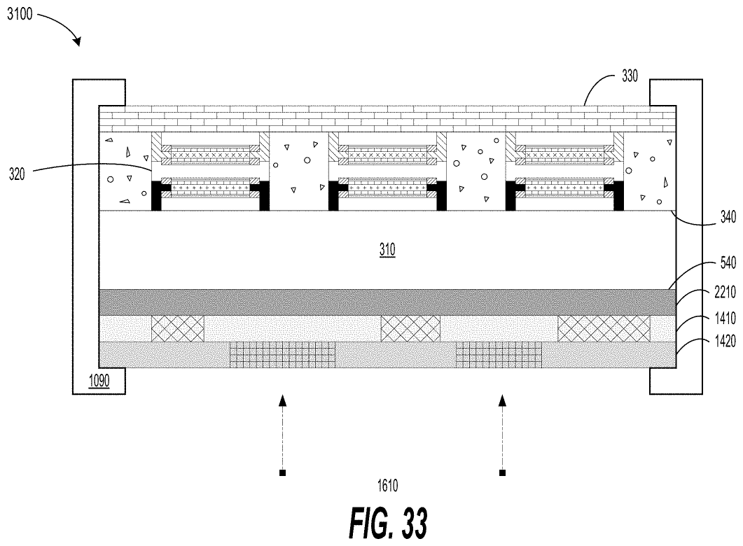

As shown in FIG. 33, another pattern of light, e.g., the pattern of light 1610 is generated, and the second stress-modification film 1420 is exposed to the pattern of light 1610 such that the pattern of light 1610 modifies the internal stress of the second stress-modification film 1420. Therefore, the modified internal stresses of the first and second stress-modification films 1410 and 1420 correspond to the bow measurement of the wafer, and the wafer is close to being flat or considered flat.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
receiving a wafer having a working surface for one or more devices to be fabricated thereon, and a backside surface opposite to the working surface;
measuring the wafer to identify bow measurement of the wafer;
forming a first stress-modification film on the backside surface, the first stress-modification film reactive to a first wavelength of light in that exposure to the first wavelength of light modifies an internal stress of the first stress-modification film; and
exposing the first stress-modification film to a pattern of the first wavelength of light to modify the internal stress of the first stress-modification film, the pattern of the first wavelength of light corresponding to the bow measurement.

2. The method of claim 1, wherein measuring the wafer to identify bow measurement of the wafer is performed prior to forming a first stress-modification film.

3. The method of claim 1, wherein measuring the wafer to identify bow measurement of the wafer is performed subsequent to forming a first stress-modification film.

4. The method of claim 1, wherein the working surface of the wafer is with one or more devices fabricated thereon, and the method further comprises:
forming a protection layer on the working surface of the wafer to protect the devices.

5. The method of claim 4, wherein measuring the wafer to identify bow measurement of the wafer is performed subsequent to forming a protection layer.

6. The method of claim 4, wherein measuring the wafer to identify bow measurement of the wafer is performed prior to forming a protection layer.

7. The method of claim 4, wherein the wafer is flipped so that the protection layer is in contact with a wafer chuck when the first stress-modification film is formed.

8. The method of claim 1, further comprising:
executing one or more lithographic patterning processes on the working surface of the wafer.

9. The method of claim 8, further comprising:
removing the first stress-modification film after the lithographic patterning processes are executed.

10. The method of claim 1, wherein the first stress-modification film is formed while the wafer is held at a periphery.

11. The method of claim 1, further comprising:
forming a second stress-modification film on the first stress-modification film, the second stress-modification film reactive to a second wavelength of light in that exposure to the second wavelength of light modifies an internal stress of the second stress-modification film; and
exposing the second stress-modification film to a pattern of the second wavelength of light to modify the internal stress of the second stress-modification film, the pattern of the second wavelength of light corresponding to the bow measurement.

12. The method of claim 11, wherein measuring the wafer to identify bow measurement of the wafer is performed subsequent to forming a second stress-modification film.

13. The method of claim 1, further comprising:
forming a stress film on the backside surface of the wafer,
wherein forming a first stress-modification film on the backside surface includes forming a first stress-modification film on the stress film.

14. The method of claim 13, further comprising:
removing a portion of the stress film; and
replacing the removed portion with a stress layer.

15. The method of claim 14, wherein the stress layer has a different stress type form the stress film.

16. A system, comprising:
a bow measurement device configured to measure a wafer to identify bow measurement of the wafer, the wafer having a working surface for one or more devices to be fabricated thereon, and a backside surface opposite to the working surface;
a stress-modification film formation device configured to form a first stress-modification film and a second stress-modification film, the first stress-modification film and the second stress-modification film reactive to first and second wavelengths of light, respectively, such that exposure to the first and second wavelengths of light modifies internal stresses of the first stress-modification film and the second stress-modification film, respectively;
a light generator configured to generate patterns of first and second wavelengths of light; and
a controller coupled to the bow measurement device, the stress-modification film formation device and the light generator, the controller configured to control the bow measurement device to measure the wafer to identify the bow measurement of the wafer, control the stress-modification film formation device to form the first stress-modification film and the second stress-modification film on the backside surface of the wafer sequentially, and control the light generator to generate and apply the pattern of first wavelength of light onto the first stress-modification film and/or the pattern of second wavelength of light onto the second stress-modification film, the pattern of first wavelength of light and the pattern of second wavelength of light corresponding to the bow measurement.

17. The system of claim 16, further comprising:
a lithographic module coupled to the controller, the lithographic module configured to be controlled by the controller to:
form a stress film on the backside surface of the wafer;
remove a portion of the stress film; and
replace the removed portion of the stress film with a stress layer.

18. The system of claim 17, wherein the stress layer has a different stress type from the stress film.

19. The system of claim 17, wherein the controller is configured to control the stress-modification film formation device to form the first stress-modification film or the first and second stress-modification films on the stress film.

20. The system of claim 16, wherein the controller is configured to first control the stress-modification film formation device to form the first stress-modification film or the first and second stress-modification films on the backside surface of the wafer and then control the bow measurement device to measure the wafer to identify the bow measurement of the wafer.
